(19) United States
(12) Patent Application Publication
(10) Pub. No.: US 2015/0160991 A1
(43) Pub. Date: Jun. 11, 2015

(54) METHOD AND DEVICE FOR PERFORMANCE EVALUATION OF FORWARD ERROR CORRECTION CODES

(71) Applicant: HUAWEI TECHNOLOGIES CO., LTD., Shenzhen (CN)

(72) Inventors: Nebojsa STOJANOVIC, Munich (DE); Yu Zhao, Munich (DE)

(73) Assignee: HUAWEI TECHNOLOGIES CO., LTD., Shenzhen (CN)

(21) Appl. No.: 14/626,367

(22) Filed: Feb. 19, 2015

Related U.S. Application Data
(63) Continuation of application No. PCT/EP2012/066790, filed on Aug. 29, 2012.

(51) Int. Cl. G06F 11/07; H03M 13/11

(52) U.S. Cl. CPC G06F 11/079; H03M 13/116

(57) ABSTRACT

The invention relates to a method for evaluating a performance of a forward error correction code used for coding a sequence of known transmit data symbols, the method comprising: receiving a sequence of receive data symbols responsive to a transmission of the known sequence of transmit data symbols over a communications channel, wherein the known sequence of transmit data symbols is transmitted over the communications channel without being coded by the forward error correction code; providing a sequence of extended parity bits based on the known transmit data symbols and based on a parity check matrix of the forward error correction code; and providing the performance of the forward error correction code based on the sequence of extended parity check bits.

### CROSS-REFERENCE TO RELATED APPLICATIONS

This application is a continuation of International Application No. PCT/EP2012/066790, filed on Aug. 29, 2012, which is hereby incorporated by reference in its entirety.

### BACKGROUND OF THE INVENTION

The present invention relates to a method and a device for evaluating a performance of a forward error correction (FEC) code, in particular for evaluating performance of FEC implemented in digital signal processing of coherent optical receivers. The present invention further relates to a method and a device for optimizing performance of intelligent networks, in particular performance of optical networks.

An important goal of long-haul optical fiber systems is to transmit the highest data throughput over the longest distance without signal regeneration in optical domain. For given constraints on the bandwidth imposed by optical amplifiers and ultimately by the fiber itself, it is important to maximize spectral efficiency. Advanced modulation formats in combination with coherent receivers enable high capacity and spectral efficiency according to ‘E. Ip and J. M. Kahn, “Digital equalization of chromatic dispersion and polarization mode dispersion,” J. Lightw. Technol. 25, 2033-2043 (2007)’.

Polarization multiplexing, quadrature amplitude modulation and coherent detection are seen as a winning combination for the next generation of high-capacity optical transmission systems since they allow information encoding in all the available degrees of freedom.

In optical systems, requirements for output bit error rate (BER) are extremely strong unlike other transmission systems. In some applications BER has to be lower than 10-15. This is the right challenge for error correction codes designers as described in ‘F. Yu, N. Stojanovic, F. N. Hauske, D. Chang, Z. Xiao, G. Bauch, D. Pflueger, C. Xie, Y. Zhao, L. Jin, Y. Li, L. Li, X. Xu, Q. Xiong, “Soft-Decision LDPC Turbo Decoding for DQPSK Modulation in Coherent Optical Receivers”, ECOC2011, We.10P1.70, (2011)’.

Basic DSP blocks of dual-polarization coherent receivers are presented in FIG. 8. After offset and gain correction 831 the four signals 824a, 824b, 824c and 824d are equalized for chromatic dispersion in frequency domain using two fast Fourier transformation (FFT) blocks 833a and 833b. Frequency offset is removed in a frequency recovery block 835. Polarization tracking, PMD compensation and residual CD compensation are done in time domain using finite impulse response (FIR) filters 837 arranged in butterfly structure. Residual frequency offset and carrier phase recovery is done in a carrier recovery block 839. Forward error correction 841 repairs incorrect bits/symbols. Conventionally, a FEC using hard information is placed on the line side. To improve system performance the FEC block 841 should be implemented in ASIC and use soft information. This way, total performance can be improved: BER, power dissipation, size and DEMUX complexity.

Most popular soft FEC codes are low density parity codes (LDPC). Encoding of LDPC codes is an important problem in their implementation. Randomly generated LDPC codes require quadratic time encoding complexity and it is not easy to implement.

Quasi-cyclic LDPC (QC-LDPC) codes encoding complexity is linearly proportional to codeword length (like algebraic codes). This placed QC-LDPC codes in main focus of researchers. Today, they are widely used in many applications. Most used codes are regular and systematic. Systematic codes quickly retrieve the information data from the corresponding codeword. Regularity enables low complex encoder/decoder realization. Regular codes are codes having the same weight of all columns in parity check matrix. The same holds for rows. Row and column weights need not to be equal. Most LDPC codes suffer from error floor that can be suppressed by careful design.

Checking FEC code performance is quite difficult and exhaustive. Common performance evaluation methods are depicted in FIG. 9. Most FEC investigations are firstly done using computer simulations 905. Next step is FPGA code implementation 907 and FEC performance estimation 909, 911 at very low BER. This kind of simulation is often used to check error floor performance.

Currently three ways of FEC performance estimation are known: Computer simulation 905, FPGA simulation 907, 909, 911 and FPGA FEC data generation 913 transmitted 915 over real link 917 and captured by sampling scope 919 for further post-processing 921. All of these methods have their own drawbacks. Computer simulation 905 is very effective for code construction and BER estimations up to the certain BER. On the other hand, the simulation cannot go to very low error rates. Transmission link modeling is quite difficult. So, FEC behavior in real applications is impossible to be judged. FPGA simulation 907, 913 requires more time for FEC code programming. FPGA simulation 907, 913 assumes some noise model (usually Gaussian) and performs simulations down to very low bit error rates (BER). Again, transmission link parameters are omitted. The third method requires more effort for FPGA implementation. The data is captured and processed by a computer. The processing speed is even lower than in the first case. However, the link behavior is included.

Behavior of FEC code in real applications is becoming very difficult. In optical transmission systems, the received signal is not only disturbed by noise. Nonlinear effects, bandwidth limitations and ASIC DSP algorithms change dramatically signal/noise statistics that can result in unexpected performance. Results obtained using Gaussian noise and simulations significantly differ from reality. The best way is to have a real link 917 including the transmitter 915 with FEC encoder 913 and receiver 919 with all DSP algorithms 921 ending with FEC decoder. This setup is nearly impossible to realize because of its high complexity when different FEC code design 901 shall be investigated.

SUMMARY

It is the object of the invention to provide a concept for an efficient method for evaluating the performance of different FEC codes in communication systems that require low bit error rates, in particular in coherent optical systems with the requirement of bit error rates lower than 10-15.

This object is achieved by the features of the independent claims. Further implementation forms are apparent from the dependent claims, the description and the figures.

There are two main aspects of the invention: A first main aspect is related to evaluating FEC performance without FEC encoder (off-line data processing; used in investigation phase; some instruments can use this algorithm also to check performance). Without encoder at the transmitter side FEC performance of almost any code can be estimated.

A second main aspect is related to products. In product, there are several FEC codes. The strongest one (larger redundancy) is used for decoding the received signal. It is assumed that decoding bits are without errors. Then, the algorithm as described below with respect to FIG. 2 is applied (no any encoding) for decoding the received signal based on the assumption that they (the received signal) are coded by the code for which the appropriate decoder is used. If no errors are observed with lower redundancy code this code can be used at the transmitter side to save power and bandwidth.

The methods/devices according to the two main aspects of the invention can be applied to both soft and hard FEC codes (no restriction). LDPC code is given as an example (soft FEC). RS code can also be applied. RS code can use soft or hard decoding algorithms. So, every code can be decoded using either hard or soft algorithms. Soft decoding provides more gain and price is complexity. However, application is not limited. For any combination of codes appropriate decoding algorithm can be derived.

In order to describe the invention in detail, the following terms, abbreviations and notations will be used:

FEC: Forward Error Correction;

ASIC: Application Specific Integrated Circuit;

BER: Bit Error Rate;

DSP: Digital Signal Processing;

DEMUX: De-multiplex;

LDPC: Low Density Parity Check;

QC-LDPC: Quasi-Cyclic Low Density Parity Check;

FPGA: Field Programmable Gate Array;

GF: Galois Field;

NCG: Net Coding Gain;

SPA: Sum Product Algorithm;

MSA: Min Sum Algorithm;

A: Log-Likelihood ratio of symbol node;

RS: Reed-Solomon:

BCH-Code: Bose-Chaudhuri-Hocquenghem Code;

DSO: Digital Sampling Oscilloscope;

FDEQ: Frequency Domain Equalizer;

SNR: Signal-to-noise ratio;

CMOS: Complementary Metal-Oxide Semiconductor;

Tx: Transmitter

Rx: Receiver;

TDEQ: Time Domain Equalizer;

CR: Carrier Recovery;

TR: Timing Recovery;

ADC: Analog-Digital-Converter;

CD: Chromatic Dispersion;

PMD: Polarization Mode Dispersion;

FFT: Fast Fourier Transform;

AGC: Automatic Gain Control;

VCO: Voltage Controlled Oscillator;

FIR: Finite Impulse Response;

According to a first aspect, the invention relates to a method for evaluating a performance of a forward error correction code used for coding a sequence of known transmit data symbols, the method comprising: receiving a sequence of receive data symbols responsive to a transmission of the known sequence of transmit data symbols over a communications channel, wherein the known sequence of transmit data symbols is transmitted over the communications channel without being coded by the forward error correction code; providing a sequence of parity bits based on the known transmit data symbols and based on a parity check matrix of the forward error correction code; and providing the performance of the forward error correction code based on the sequence of parity check bits.

When providing a sequence of parity bits based on the known transmit data symbols and based on a parity check matrix of the forward error correction code, an encoding prior to transmission can be omitted, thereby saving processing complexity. The method provides an efficient procedure for testing the performance of different FEC codes in communication systems that require low bit error rates. In particular, the method provides an efficient mechanism to test the performance of coherent optical systems with the requirement of bit error rates down to 10-15 and make decision based on FEC curve that is known in advance.

In a first possible implementation form of the method according to the first aspect, an uncoded data word of N bits is passed through the parity check matrix to generate a new column of the parity check matrix, thereby building an extended parity matrix.

By transmitting a non FEC-coded sequence of transmit symbols, a high complex encoder at transmission side can be saved thus reducing complexity of testing.

In a second possible implementation form of the method according to the first aspect, an additional N+1 bit in the extended parity check matrix in the predetermined row is calculated based on the uncoded data word of N bits and a predetermined row of the parity check matrix.

Parity checking the known transmit data symbols over the parity check matrix is easy to implement. Testing the code is simple by applying the parity check matrix to the known transmit data symbols. The correct code satisfies all matrix equations of the extended parity check matrix. If the transmission is distorted by noise, the parity check matrix decides the noisy signal providing the same performance as the original non-extended code.

In a third possible implementation form of the method according to the first aspect as such or according to any of the preceding implementation forms of the first aspect, the known transmit data symbols are known random data symbols.

In a fourth possible implementation form of the method according to the first aspect as such or according to any of the preceding implementation forms of the first aspect, the forward error correction code is a low density parity check code, in particular a quasi-circular low density parity check code.

Most popular soft FEC codes are low density parity check (LDPC) codes. While randomly generated LDPC codes require quadratic time encoding complexity and are not easy to implement, quasi-cyclic LDPC codes have an encoding complexity which is linearly proportional to code word length, i.e. reduced complexity. Therefore, implementation of QC-LDPC codes is easy.

In a fifth possible implementation form of the method according to the fourth implementation form of the first aspect, the method further comprises: decoding the sequence of receive data symbols by an LDPC decoding algorithm using a parity check matrix for decoding, in particular one of a sum product algorithm and a min sum algorithm (or other similar algorithms), wherein the LDPC decoding algorithm is configured to use the sequence of extended parity bits.

Conventional LDPC decoding algorithms can easily be adapted for using the sequence of extended parity bits.

In a sixth possible implementation form of the method according to the fifth implementation form of the first aspect, the decoding algorithm is a sum product algorithm that decodes the sequence of receive data symbols by applying the equation:

$${Λ}_{m \to n} ( {u}_{n} ) = 2 {tan h}^{- 1} \{ {B}^{b} ( m ) {\prod }_{{n}^{′} ∈ N ( m ) ∖ n} tan h [ {λ}_{{n}^{′} \to m} ( {u}_{{n}^{′}} ) / 2 ] \} ,$$

where m represents a check node and n represents a symbol node of the QC-LDPC code, λ represents log-likelihood ratio of a symbol node, N(m)/n represents bits from all symbol nodes contributing to check node n excluding bit of symbol node n, Λ represents log-likelihood ratio of the receive data symbol un at symbol node n and Bb(m) represents a vector of extended parity bits.

By using Bb(m) representing the vector of binary numbers describing the sequence of noise samples, decoding performance for a non FEC-coded transmit data sequence is approximated to decoding performance for an FEC-coded transmit data sequence, thereby allowing to save the FEC encoder at transmission side. The decoding complexity is similar to a decoding complexity of an SPA algorithm.

In a seventh possible implementation form of the method according to the fifth implementation form of the first aspect, the decoding algorithm is a min sum algorithm that decodes the sequence of receive data symbols by applying the equation:

$${Λ}_{m \to n} ( {u}_{n} ) = {min}_{{n}^{′} ∈ N ( m ) ∖ n} \vert {λ}_{{n}^{′} \to m} ( {u}_{{n}^{′}} ) \vert {B}^{b} ( m ) {\prod }_{{n}^{′} ∈ N ( m ) ∖ n} sgn [ {λ}_{{n}^{′} \to m} ( {u}_{{n}^{′}} ) ] ,$$

where m represents a check node and n represents a symbol node of the QC-LDPC code, λ represents log-likelihood ratio of a symbol node, N(m)/n represents bits from all symbol nodes contributing to check node n excluding bit of symbol node n, Λ represents log-likelihood ratio of the noisy information code word un at symbol node n and Bb(m) represents a vector of extended parity bits.

By using Bb(m) representing the vector of binary numbers describing the sequence of noise samples, decoding performance for a non FEC-coded transmit data sequence is approximated to decoding performance for an FEC-coded transmit data sequence, thereby allowing to save the FEC encoder at transmission side. The decoding complexity is similar to a decoding complexity of an MSA algorithm.

According to a second aspect, the invention relates to a device for evaluating a performance of a forward error correction code used for coding a sequence of known transmit data symbols, the device comprising: a receiver configured for receiving a sequence of receive data symbols responsive to a transmission of the known sequence of transmit data symbols over a communications channel, wherein the known sequence of transmit data symbols is transmitted over the communications channel without being coded by the forward error correction code; and a processor configured for providing a sequence of extended parity bits (Bb) based on the known transmit data symbols (D) and based on a parity check matrix (H) of the forward error correction code; and configured for providing the performance of the forward error correction code based on the sequence of extended parity check bits (Bb).

When providing a sequence of extended parity bits based on the known transmit data symbols and based on a parity check matrix of the forward error correction code, an encoding prior to transmission can be omitted, thereby saving processing complexity. The device is thus efficient for testing the performance of different FEC codes in communication systems that require low bit error rates. In particular, the device is an efficient tool for testing the performance of coherent optical systems with the requirement of bit error rates down to 10-15.

According to a third aspect, the invention relates to a method for optimizing performance of intelligent networks, the method comprising: receiving a sequence of receive data symbols responsive to a transmission of a sequence of transmit data symbols over a communications channel, wherein the sequence of transmit data symbols is encoded by a first forward error correction code; decoding the sequence of receive data symbols by a decoder configured to decode the first forward error correction code providing a sequence of decoded receive data symbols without errors; providing a first sequence of parity bits based on the sequence of decoded receive data symbols and based on a parity check matrix of the first forward error correction code; and providing a performance of the first forward error correction code based on the first sequence of parity bits; providing a second sequence of parity bits based on the sequence of decoded receive data symbols and based on a parity check matrix of a second forward error correction code, wherein a code redundancy of the second forward error correction code is lower than a code redundancy of the first forward error correction code; and providing a performance of the second forward error correction code based on the second sequence of parity bits; and encoding the sequence of transmit data symbols by the second forward error correction code if the performance of the second forward error correction code fulfills a predetermined criterion.

When using a method according to the third aspect, performance of FEC codes can be adapted to the need of the communications channel. The method is able to find a forward error correction code providing low bit error rate at low code redundancy, thereby improving efficiency of FEC coding. Power efficiency is improved since lower complexity encoder and decoder are used. BER performance must be the same, e.g. below 10-15. For a certain link the SNR is constant, e.g. 6 dB. For this SNR value, the FEC with 20% redundancy will provide BER below 10-15. However, the FEC with 7% redundancy will also provide BER below 10-15

In a first possible implementation form of the method according to the third aspect as such, the predetermined criterion is a bit error rate being lower than a predetermined threshold.

When using a bit error rate being lower than a predetermined threshold as predetermined criterion, the method is able to find accurate FEC codes that deliver coding at the desired bitrate. Alternatively or additionally the performance of the second forward error correction code can be compared to the performance of the first forward error correction code.

In a second possible implementation form of the method according to the third aspect as such or according to the first implementation form of the third aspect, the first forward error correction code is one of a soft FEC code and a hard FEC code; and the second forward error correction code is one of a soft FEC code and a hard FEC code. If the second code is hard FEC the first FEC should also be hard FEC. Yet, other combinations are allowed, too.

Soft FEC codes provide higher coding gain while hard FEC codes have lower implementation complexity.

In a third possible implementation form of the method according to the third aspect as such or according to any of the preceding implementation forms of the third aspect, the first forward error correction code is a concatenated code comprising an inner code, in particular an inner QC-LDPC code, and an outer code, in particular an outer Reed-Solomon code.

The method can be applied to different types of codes, which are concatenated by each other. Concatenated codes provide higher coding gains. Using the method according to the third aspect as such or according to any of the preceding implementation forms of the third aspect reduces complexity for testing concatenated codes.

According to a fourth aspect, the invention relates to a device for optimizing performance of intelligent networks, the device comprising: a receiver configured for receiving a sequence of receive data symbols responsive to a transmission of a sequence of transmit data symbols over a communications channel, wherein the sequence of transmit data symbols is encoded by a first forward error correction code; a processor configured for decoding the sequence of receive data symbols by a decoder configured to decode the first forward error correction code providing a sequence of decoded receive data symbols; configured for providing a first sequence of parity bits based on the sequence of decoded receive data symbols and based on a parity check matrix of the first forward error correction code and providing a performance of the first forward error correction code based on the first sequence of parity bits; and configured for providing a second sequence of parity bits based on the sequence of decoded receive data symbols and based on a parity check matrix of a second forward error correction code, wherein a code redundancy of the second forward error correction code is lower than a code redundancy of the first forward error correction code; and providing a performance of the second forward error correction code based on the second sequence of parity bits; and a controller configured for providing a control signal enabling a transmitter for encoding the sequence of transmit data symbols by the second forward error correction code if the performance of the second forward error correction code fulfills a predetermined criterion.

The first code, i.e. the code in use, provides the decoded signal that is the transmitted signal without noise. It includes information bits and parity bits. Codeword consist of information bits and parity bits that are added after encoding.

When using a device according to the fourth aspect, performance of FEC codes can be adapted to the need of the communications channel. The device is able to find a forward error correction code providing low bit error rate at low code redundancy, thereby improving efficiency of FEC coding.

In a first possible implementation form of the fourth aspect, the device comprises an interface to a flash memory, wherein the second performance estimator is configured to load the second forward error correction code via the interface to the flash memory.

By an interface to a flash memory, the processor may load different forward error correction codes via the interface and test the different codes sequentially or even in parallel.

The testing speed of the device is lower than the CMOS ASIC data processing. However, many codes can be sequentially checked in parallel with real data processing. The device (FEC checker) may be implemented on a chip (reconfigurable CMOS ASIC) and work in parallel with the used FEC encoder for short period of time during searching over FEC codes. When searching is finished the device is off.

According to a fifth aspect, the invention relates to a computer program loadable by a program interface of the processor of the device according to the fourth aspect as such or according to the first implementation form of the fourth aspect, the computer program implementing the FEC decoder.

According to a sixth aspect, the invention relates to a coherent optical receiver comprising a device according to the second aspect for evaluating a performance of FEC coding or a device according to the fourth aspect for optimizing performance of intelligent networks.

These and other aspects of the invention will be apparent from the embodiment(s) described below.

### BRIEF DESCRIPTION OF THE DRAWINGS

Further embodiments of the invention will be described with respect to the following figures, in which:

FIG. 1 shows a schematic diagram of a method for evaluating a performance of a forward error correction code according to an implementation form;

FIG. 2 shows a schematic diagram of a method for optimizing performance of intelligent networks according to an implementation form;

FIG. 3 shows a diagram illustrating bit error rates of methods for evaluating FEC performance according to implementation forms versus bit error rates of conventional FEC testing methods;

FIG. 4 shows a schematic diagram of a method for evaluating a performance of a forward error correction code according to an implementation form;

FIG. 5 shows a schematic diagram of a method for evaluating a performance of a forward error correction code according to an implementation form;

FIG. 6 shows block diagrams of a device 600a for evaluating a performance of a forward error correction code according to an implementation form and of a device 600b for optimizing performance of intelligent networks according to an implementation form;

FIG. 7 shows a block diagram of a device for optimizing performance of intelligent networks according to an implementation form;

FIG. 8 shows a block diagram of a digital signal processing part of a conventional dual-polarization coherent receiver; and

FIG. 9 shows a schematic diagram of conventional methods for testing performance of forward error correction codes.

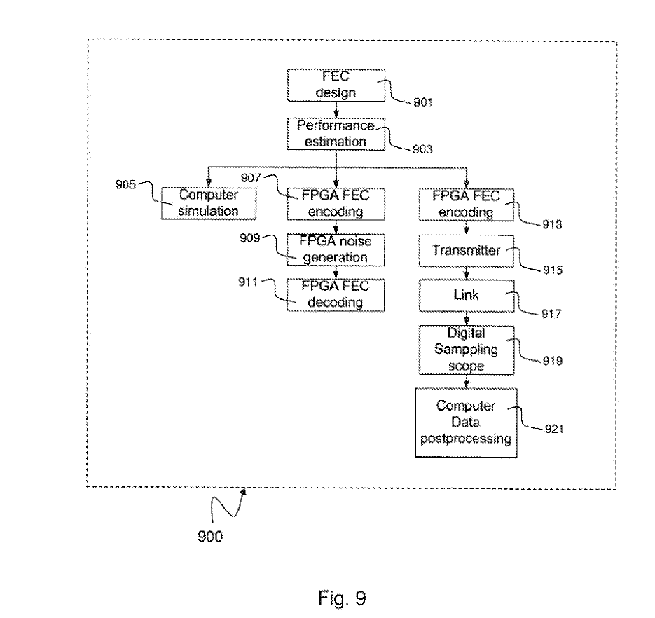

### DETAILED DESCRIPTION OF EMBODIMENTS OF THE INVENTION

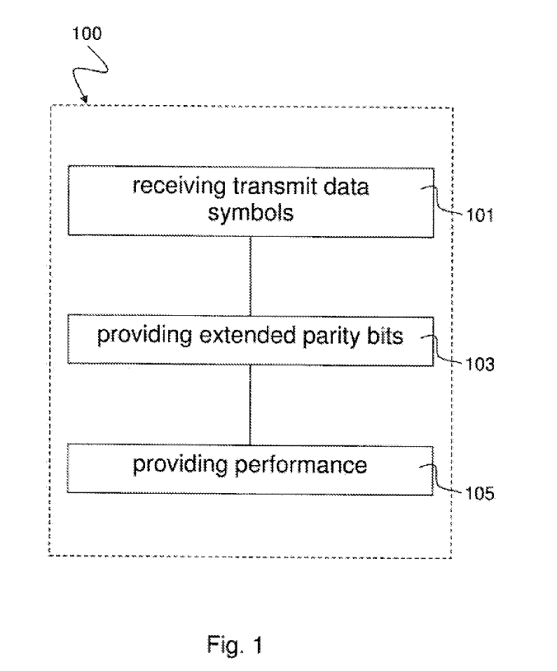

FIG. 1 shows a schematic diagram of a method 100 for evaluating a performance of a forward error correction code according to an implementation form. The method 100 is for evaluating a performance of a forward error correction code used for coding a sequence of known transmit data symbols.

The method 100 comprises receiving 101 a sequence of receive data symbols responsive to a transmission of the known sequence of transmit data symbols over a communications channel, wherein the known sequence of transmit data symbols is transmitted over the communications channel without being coded by the forward error correction code.

The method 100 further comprises: providing 103 a sequence of extended parity bits based on the known transmit data symbols and based on a parity check matrix of the forward error correction code.

The method 100 further comprises: providing 105 the performance of the forward error correction code based on the sequence of extended parity check bits.

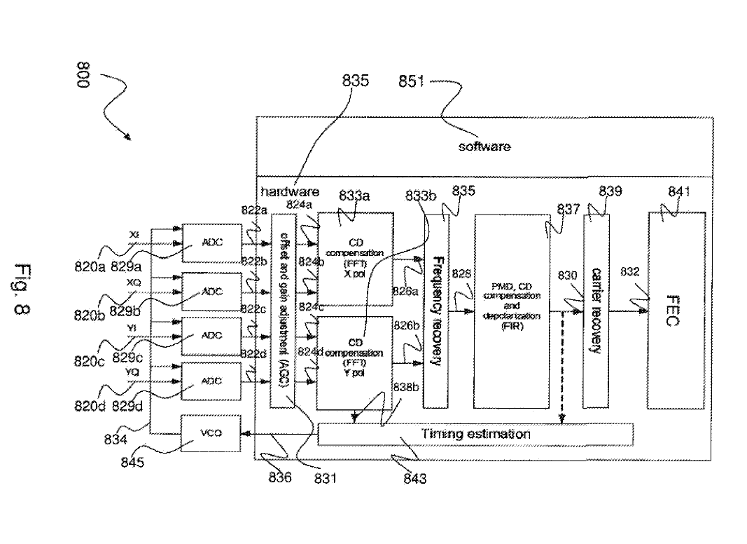

In an implementation form, the communications channel is an optical transmission link. In an implementation form, the sequence of receive data symbols is received by a coherent optical receiver as described with respect to FIG. 8.

In the following, an implementation form of the method 100 is described for performance estimation of QC-LDPC codes.

A QC-LDPC code is given by the null space of an array of sparse circulants of the same size. For two positive integers c and t (c<=t), the parity check matrix of QC-LDPC code is a c×t array of k×k circulants over GF(2). Each circulant is derived from a k×k identity matrix by appropriate column shift. Such a code is regular since row weights are identical and equal to c and all row weights are equal to t.

A circulant matrix C also called a circulant is fully specified by one vector c, which appears as the first column of the circulant matrix C. The remaining columns of C are each cyclic permutations of the vector c with offset equal to the column index. The last row of C is the vector c in reverse order, and the remaining rows are each cyclic permutations of the last row.

Carefully designed regular codes enable high net coding gain (NCG), moderate code word lengths and acceptable error floor. Two decoding algorithms with similar performance, sum product algorithm (SPA) and min sum algorithm (MSA) are often explored for decoding. There are many other variants and simplifications of the original decoding algorithm. Main difference is in the check-node update. In two equations below, update is done from check node m to symbol node n. Log-likelihood ratio of symbol node is denoted by λ. N(m) denotes all bits (symbol) contributing in check node m. N(m)\n denotes the set of all bits contributing in check node m excluding bit n. The SPA slightly outperforms the MSA and the price is very high complexity. Therefore, the MSA is often implemented in real products.

The QC-LDPC code uses the following parity matrix:

$$H = ( \begin{matrix}{A}_{1 , 1} & {A}_{1 , 2} & … & {A}_{1 , t} \\ {A}_{2 , 1} & {A}_{2 , 2} & … & … \\ … & … & … & … \\ {A}_{c , 1} & {A}_{1 , 2} & … & {A}_{c , t}\end{matrix} ) .$$

The SPA algorithm performs the equation:

$${Λ}_{m \to n} ( {u}_{n} ) = 2 {tan h}^{- 1} \{ {\prod }_{{n}^{′} ∈ N ( m ) ∖ n} tan h [ {λ}_{{n}^{′} \to m} ( {u}_{{n}^{′}} ) / 2 ] \} .$$

The MSA algorithm performs the equation:

$${Λ}_{m \to n} ( {u}_{n} ) = {min}_{{n}^{′} ∈ N ( m ) ∖ n} \vert {λ}_{{n}^{′} \to m} ( {u}_{{n}^{′}} ) \vert {\prod }_{{n}^{′} ∈ N ( m ) ∖ n} sgn [ {λ}_{{n}^{′} \to m} ( {u}_{{n}^{′}} ) ] .$$

The correct code word should satisfy all c×k equations. Vector B is defined as a vector of length c×k for any random vector D of length c×t such as that it holds BT=H×DT. The method 100 is applied by modifying the decoding rules of SPA and MSA algorithm as

$${Λ}_{m \to n} ( {u}_{n} ) = 2 {tan h}^{- 1} \{ {B}^{b} ( m ) {\prod }_{{n}^{′} ∈ N ( m ) ∖ n} tan h [ {λ}_{{n}^{′} \to m} ( {u}_{{n}^{′}} ) / 2 ] \}$$

$${Λ}_{m \to n} ( {u}_{n} ) = {min}_{{n}^{′} ∈ N ( m ) ∖ n} \vert {λ}_{{n}^{′} \to m} ( {u}_{{n}^{′}} ) \vert {B}^{b} ( m ) {\prod }_{{n}^{′} ∈ N ( m ) ∖ n} sgn [ {λ}_{{n}^{′} \to m} ( {u}_{{n}^{′}} ) ]$$

where Bb represents a binary signal. Note that mapping is done as

0→1

1→−1

When applying the method 100, the LDPC decoder uses uncoded data, vector B and parity check matrix H to decode data sequence.

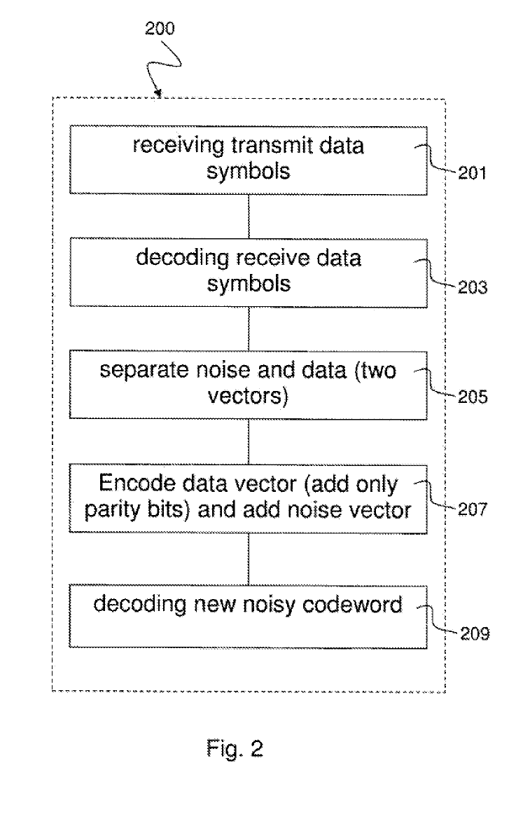

FIG. 2 shows a schematic diagram of a method 200 for optimizing performance of intelligent networks according to an implementation form.

The method 200 comprises: receiving 201 a sequence of receive data symbols responsive to a transmission of a sequence of transmit data symbols over a communications channel, wherein the sequence of transmit data symbols is encoded by a first forward error correction code.

The method 200 comprises: decoding 203 the sequence of receive data symbols by a decoder configured to decode the first forward error correction code providing a sequence of decoded receive data symbols.

The method 200 comprises: providing 205 a first sequence of extended parity bits based on the sequence of decoded receive data symbols and based on a parity check matrix of the first forward error correction code; and providing a performance of the first forward error correction code based on the first sequence of extended parity bits.

The method 200 comprises: providing 207 a second sequence of extended parity bits based on the sequence of decoded receive data symbols and based on a parity check matrix (H) of a second forward error correction code, wherein a code redundancy of the second forward error correction code is lower than a code redundancy of the first forward error correction code; and providing a performance of the second forward error correction code based on the second sequence of extended parity bits.

The method 200 comprises: encoding 209 the sequence of transmit data symbols by the second forward error correction code if the performance of the second forward error correction code fulfills a predetermined criterion.

In an implementation form, the method 200 comprises: receiving transmit data

symbols 201; decoding receive data symbols 203; separating noise and data in two vectors 205; encoding data vector by adding only parity bits and adding noise vector 207; and decoding new noisy codeword 209.

In an implementation form, the communications channel is an optical transmission link. In an implementation form, the intelligent network is an optical network. In an implementation form, the sequence of receive data symbols is received by a coherent optical receiver as described with respect to FIG. 8.

In an implementation form, the providing 205 the first sequence of extended parity bits corresponds to the providing 103 the sequence of extended parity bits as described with respect to FIG. 1. In an implementation form, the providing 207 the second sequence of extended parity bits corresponds to the providing 103 the sequence of extended parity bits as described with respect to FIG. 1. In an implementation form, the performance of the second forward error correction code is determined according to the providing 105 the performance of the forward error correction code as described with respect to FIG. 1.

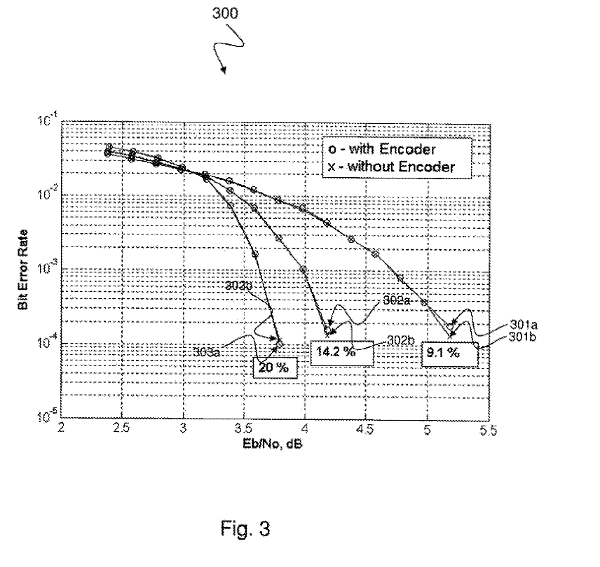

FIG. 3 shows a diagram 300 illustrating bit error rates of methods for evaluating FEC performance according to implementation forms versus bit error rates of conventional FEC testing methods.

FIG. 3 demonstrates the correctness of the method according to aspects of the invention. Three QC-LDPC codes of length approximately equal to 18000 were simulated.

The code redundancy is 9, 14 and 20%. The number of code words is 50 and the LDPC decoder did 5 iterations. Results with and without LDPC encoder are almost the same which can be seen by the graphs. The first two graphs 301a and 301b illustrate the performance of an LDPC code with 9.1% code redundancy when an encoder is applied 301a and when the encoder is not applied 301b. The second two graphs 302a and 302b illustrate the performance of an LDPC code with 14.2% code redundancy when an encoder is applied 302a and when the encoder is not applied 302b. The third two graphs 303a and 303b illustrate the performance of an LDPC code with 20% code redundancy when an encoder is applied 303a and when the encoder is not applied 303b.

The small difference comes from different noise generator seed. The simulation results prove that the LDPC encoder is not necessary to be implemented or simulated in FEC performance testing implementations.

This method can be implemented for any code using parity matrix for soft decoding. Especially, large effort is required to find the generator matrix of irregular codes that encoding complexity can be quadratic with code word length. This effort can be reduced when implementing methods according to aspects of the invention.

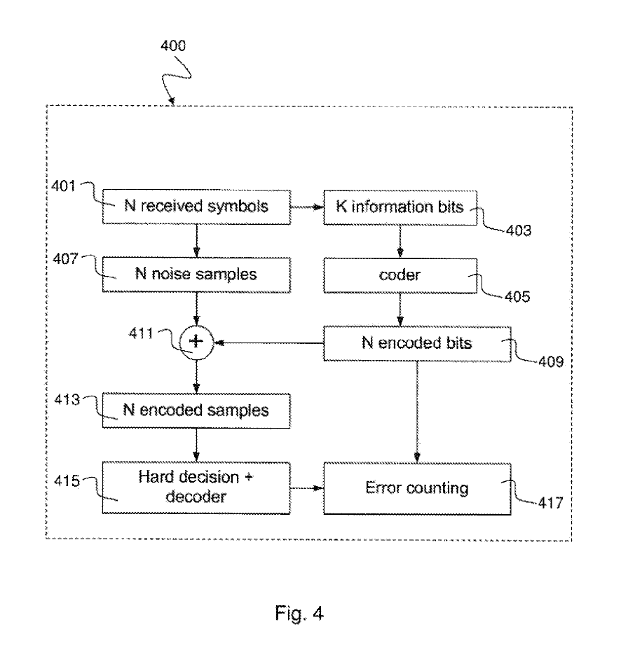

FIG. 4 shows a schematic diagram of a method 400 for evaluating a performance of a forward error correction code according to an implementation form.

The method can be extended to investigate hard decision codes like RS, BCH or product codes. FIG. 4 presents an extension to single hard decision block code. N noise symbols are received 401. From this data block K information symbols 403 (no noise) and N noisy samples 407 are extracted. K information bits are coded 405 to obtain the code word of length N 409. Encoded data 409 and noise pattern 407 are added 411 and provided as N encoded samples 413 to the limiter and decoder 415. Data sequence is decoded and compared to the original sequence. Thereafter, bit error rate is calculated 417.

To estimate product code performance, the same method can be applied. When supposing that the two-dimensional product code consists of N BCH code words per each dimension, K×K matrix of data 403 and N×N matrix of noise 407 are extracted. Data are encoded 409 and samples are added 411 as described with respect to FIG. 4. After hard decision and decoding 415 the code performance is derived by using error counting 417.

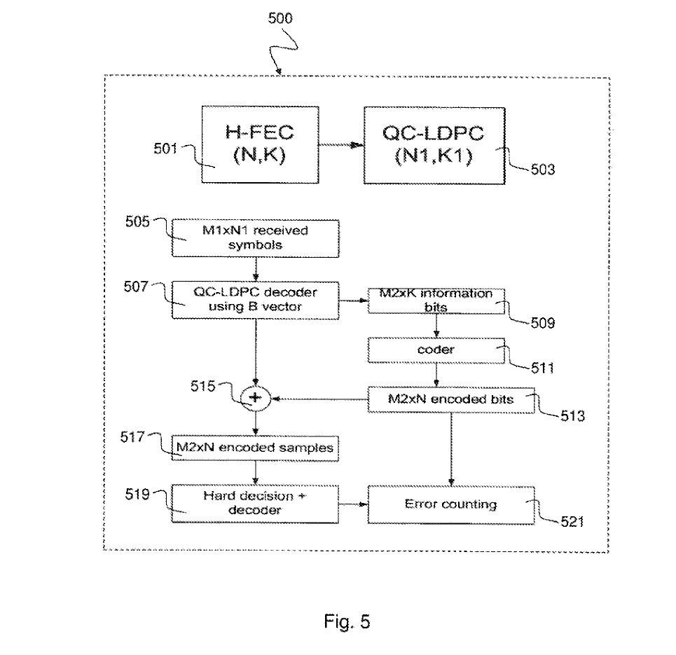

FIG. 5 shows a schematic diagram of a method 500 for evaluating a performance of a forward error correction code according to an implementation form.

The FEC code comprises a code concatenation of an inner QC-LDPC code 503 and an outer code 501, e.g. a RS code. M1×N1 samples are selected 505 to realize decoding method. This number of samples comprises M1 QC-LDPC code words and M2 RS code words. N1 describes the code word length and M2 describes the floor function of M1×N1/N. Using vectors B that support LDPC decoding in 507, the noisy data in front of H-FEC 501 are derived. H-FEC decoding is already described with respect to FIG. 4.

Hard decoding does not include some pattern dependent noise on parity bits. Since the redundancy is below 25% in optical systems that will not significantly hurt the FEC performance estimation. In linear region, this will not have noticeable effects.

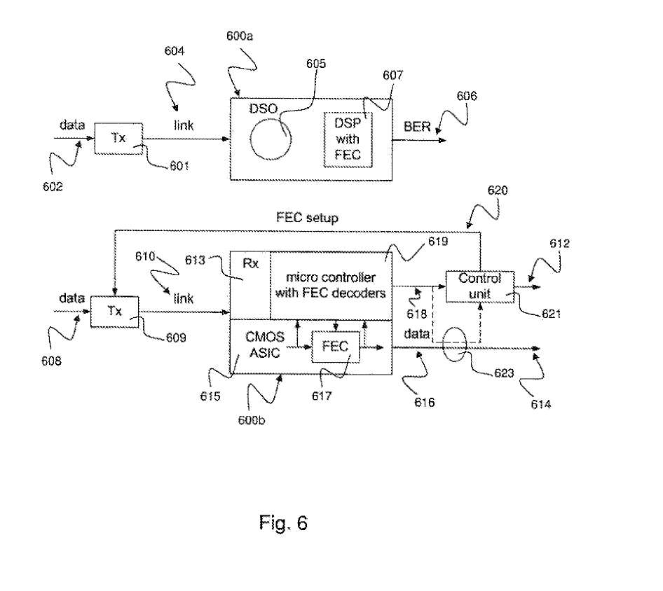

FIG. 6 shows block diagrams of a device 600a for evaluating a performance of a forward error correction code according to an implementation form and of a device 600b for optimizing performance of intelligent networks according to an implementation form.

Methods 100 as described with respect to one of FIGS. 1 to 5 can be implemented in devices 600a for evaluating FEC code performance or in devices 600b for optimizing performance of intelligent networks.

In a communications system, e.g. an optical communications system, a transmitter Tx 601 is used for transmitting data 602 over a link 604 to a device 600a for evaluating FEC code performance. The device 600a comprises a (digital) sampling scope (DSO) 605 using DSP algorithms to estimate link performance together with FEC 607. Link performance can be represented as bit error rate (BER) 606.

In a communications system, e.g. an optical communications system, a transmitter Tx 609 is used for transmitting data 608 over a link 610 to a device 600b for optimizing performance of intelligent networks. The device 600b for optimizing performance of intelligent networks comprises a receiver 613 receiving the transmitted data 608, a micro controller with FEC decoders 619 and a CMOS ASIC 615 implementing an FEC circuit 617.

The device 600b further comprises a control unit 621 with a feed-back loop to the transmitter 609.

Devices 606b, e.g. implemented in real products, have the possibility to periodically load data to micro controller 619 that can choose any FEC code 617 and estimate link performance with the chosen code. This enables better network management.

The transmission may start with most complex FEC and largest redundancy. The micro controller 619 can check performance of all implemented codes. The report can be sent to the central management units that can later reconfigure FEC. For example instead to use code word of length 50000 and redundancy of 20% central management can select the code with length 10000 and redundancy of 15% that saves bandwidth and power dissipation without loss of performance.

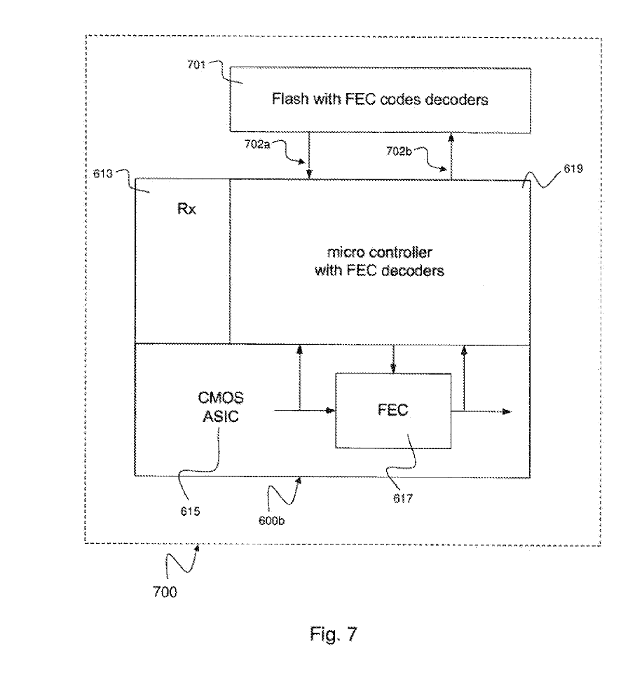

FIG. 7 shows a block diagram of a device 700 for optimizing performance of intelligent networks according to an implementation form.

The device 700 comprises a device 600b as described with respect to FIG. 6 and a flash 701 with FEC codes decoders coupled to the device 600b via an RX interface 702a receiving data and a TX interface 702b transmitting data.

In future optical transponders sending and recovering super-channel carrying more than 1 Tb data has a significant importance. A super channel may consist of 10 sub-channels (e.g. 10×100G). During link establishment the FEC with maximum performance can be used to assure the acceptable performance. In an implementation form, an array of codes 617 is checked one by one in the micro controller 619.

In a first step, noisy data before CMOS ASIC FEC are loaded to the microcontroller together with decoded data that are assumed to be error free. In a second step, the micro controller loads decoding algorithms from the flash memory and estimates error rate. The decoding is error free when all parity equations are fulfilled or when the syndromes (H-FEC) are equal to zero. In a third step, since the micro controller has information about the code redundancy, some codes can be selected even though they produce errors. If these errors are in certain (acceptable) limits the micro controller can estimate the code performance including the code redundancy. For example, the difference in required SNR between 10% and 20% FEC codes is 0.4 dB. If 20% FEC is used and 10% FEC produces errors that surely do not exist with 0.4 dB higher SNR, the lower redundancy FEC can be selected. The code selection method prevents some effects like aging and link temperature changes. The best power efficient code can always be selected.

From the foregoing, it will be apparent to those skilled in the art that a variety of devices, methods, systems, computer programs on recording media, and the like, are provided.

The present disclosure also supports a computer program product including computer executable code or computer executable instructions that, when executed, causes at least one computer to execute the performing and computing steps described herein.

The present disclosure also supports a system configured to execute the performing and computing steps described herein.

Many alternatives, modifications, and variations will be apparent to those skilled in the art in light of the above teachings. Of course, those skilled in the art readily recognize that there are numerous applications of the invention beyond those described herein. While the present inventions has been described with reference to one or more particular embodiments, those skilled in the art recognize that many changes may be made thereto without departing from the scope of the present invention. It is therefore to be understood that within the scope of the appended claims and their equivalents, the inventions may be practiced otherwise than as specifically described herein.

1. A method for evaluating a performance of a forward error correction (FEC) code used for coding a sequence of known transmit data symbols, the method comprising:
receiving a sequence of receive data symbols responsive to a transmission of the known sequence of transmit data symbols over a communications channel, wherein the known sequence of transmit data symbols is transmitted over the communications channel without being coded by the FEC code;
providing a sequence of extended parity bits based on the known transmit data symbols and based on a parity check matrix of the FEC code; and
providing the performance of the FEC code based on the sequence of extended parity check bits.

2. The method of claim 1, wherein an uncoded data word of N bits is passed through the parity check matrix to generate a new column of the parity check matrix, thereby building an extended parity check matrix.

3. The method of claim 2, wherein an additional N+1 bit in the extended parity check matrix in the predetermined row is calculated based on the uncoded data word of N bits and a predetermined row of the parity check matrix.

4. The method of claim 1, wherein the known transmit data symbols are known random data symbols.

5. The method of claim 1, wherein the FEC code is a quasi-circular low density parity check (QC-LDPC) code.

6. The method of claim 5, further comprising:
decoding the sequence of receive data symbols by an LDPC decoding algorithm using a parity check matrix for decoding, in particular one of a sum product algorithm and a min sum algorithm, wherein the LDPC decoding algorithm is configured to use the sequence of extended parity bits.

7. The method of claim 6, wherein the decoding algorithm is a sum product algorithm that decodes the sequence of receive data symbols by applying the equation:
$${Λ}_{m \to n} ( {u}_{n} ) = 2 {tan h}^{- 1} \{ {B}^{b} ( m ) {\prod }_{{n}^{′} ∈ N ( m ) ∖ n} tan h [ {λ}_{{n}^{′} \to m} ( {u}_{{n}^{′}} ) / 2 ] \} ,$$
where m represents a check node and n represents a symbol node of the QC-LDPC code, λ represents log-likelihood ratio of a symbol node, N(m)/n represents bits from all symbol nodes contributing to check node m excluding bit of symbol node n, Λ represents log-likelihood ratio of the receive data symbol uₙ at symbol node n and B^{b}(m) represents a vector of extended parity bits.

8. The method of claim 6, wherein the decoding algorithm is a min sum algorithm that decodes the sequence of receive data symbols by applying the equation:
$${Λ}_{m \to n} ( {u}_{n} ) = {min}_{{n}^{′} ∈ N ( m ) ∖ n} \vert {λ}_{{n}^{′} \to m} ( {u}_{{n}^{′}} ) \vert {B}^{b} ( m ) {\prod }_{{n}^{′} ∈ N ( m ) ∖ n} sgn [ {λ}_{{n}^{′} \to m} ( {u}_{{n}^{′}} ) ] ,$$
where m represents a check node and n represents a symbol node of the QC-LDPC code, λ represents log-likelihood ratio of a symbol node, N(m)/n represents bits from all symbol nodes contributing to check node m excluding bit of symbol node n, Λ represents log-likelihood ratio of the noisy information code word uₙ at symbol node n and B^{b}(m) represents a vector of extended parity bits.

9. A device for evaluating a performance of a forward error correction (FEC) code used for coding a sequence of known transmit data symbols, the device comprising:
a receiver configured for receiving a sequence of receive data symbols responsive to a transmission of the known sequence of transmit data symbols over a communications channel, wherein the known sequence of transmit data symbols is transmitted over the communications channel without being coded by the FEC code; and
a processor configured for providing a sequence of extended parity bits based on the known sequence of transmit data symbols and based on a parity check matrix of the FEC code;
and configured for providing the performance (606) of the FEC code based on the sequence of extended parity check bits.

10. A method for optimizing performance of intelligent networks, the method comprising:
receiving a sequence of receive data symbols responsive to a transmission of a sequence of transmit data symbols over a communications channel, wherein the sequence of transmit data symbols is encoded by a first FEC code;
decoding the sequence of receive data symbols by a decoder configured to decode the first FEC code providing a sequence of decoded receive data symbols without errors;
providing a first sequence of parity bits based on the sequence of decoded receive data symbols and based on a parity check matrix of the first FEC code; and providing a performance of the first FEC code based on the first sequence of parity bits;
providing a second sequence of parity bits based on the sequence of decoded receive data symbols and based on a parity check matrix of a second FEC code, wherein a code redundancy of the second FEC code is lower than a code redundancy of the first FEC code; and
providing a performance of the second FEC code based on the second sequence of parity bits; and
encoding the sequence of transmit data symbols by the second FEC code if the performance of the second FEC code fulfills a predetermined criterion.

11. The method of claim 10, wherein the predetermined criterion is a bit error rate being lower than a predetermined threshold.

12. The method of claim 10, wherein the first FEC code is one of a soft FEC code and a hard FEC code; and wherein the second FEC code is one of a soft FEC code and a hard FEC code.

13. The method of claim 10, wherein the first FEC code is a concatenated code comprising an inner code, in particular an inner QC-LDPC code, and an outer code, in particular an outer Reed-Solomon code.

14. A device for optimizing performance of intelligent networks, the device comprising:
a receiver configured for receiving a sequence of receive data symbols responsive to a transmission of a sequence of transmit data symbols over a communications channel, wherein the sequence of transmit data symbols is encoded by a first FEC code;
a processor configured for decoding the sequence of receive data symbols by a decoder configured to decode the first FEC code providing a sequence of decoded receive data symbols;
configured for providing a first sequence of parity bits (B^{b}) based on the sequence of decoded receive data symbols (D) and based on a parity check matrix (H) of the first FEC code and providing a performance of the first FEC code based on the first sequence of parity bits (B^{b}); and
configured for providing a second sequence of parity bits (B^{b}) based on the sequence of decoded receive data symbols (D) and based on a parity check matrix (H) of a second FEC code, wherein a code redundancy of the second FEC code is lower than a code redundancy of the first FEC code; and providing a performance of the second FEC code based on the second sequence of parity bits (B^{b}); and
a controller configured for providing a control signal enabling a transmitter for encoding the sequence of transmit data symbols by the second FEC code if the performance of the second FEC code fulfills a predetermined criterion.

15. The device of claim 14, comprising an interface to a flash memory, wherein the second performance estimator is configured to load the second FEC code via the interface to the flash memory.
